(19) United States
(12) Patent Application Publication
(10) Pub. No.: US 2020/0227583 A1
(43) Pub. Date: Jul. 16, 2020

(54) SOLAR CELL EMITTER REGION FABRICATION APPARATUS

(71) Applicant: SUNPOWER CORPORATION, SAN JOSE, CA (US)

(72) Inventors: Xiao BAI, Fremont, CA (US); Taiqing QIU, Los Gatos, CA (US)

(21) Appl. No.: 16/342,509

(22) PCT Filed: Oct. 4, 2017
(86) PCT No.: PCT/US2017/055071

§ 371 Date: Apr. 16, 2019

Related U.S. Application Data
(60) Provisional application No. 62/411,474, filed on Oct. 21, 2016.

(51) Int. Cl. H01L 31/18; H01J 37/317

(52) U.S. Cl. CPC H01L 31/1804; H01J 37/08; H01J 37/3171

(57) ABSTRACT

Solar cell emitter regions fabrication is described. In an example, a species mask, e.g., a shadow mask, is provided between a plasma source and a semiconductor wafer. The species mask includes an opening pattern having several openings with respective opening widths and pitches. Species emitted by the plasma source pass through the openings in the species mask and implant in the semiconductor wafer to form several emitter region fingers having respective finger widths and pitches. In an embodiment, the opening widths and pitches vary across the species mask and the emitter region finger widths and pitches are uniform across the semiconductor wafer.

### TECHNICAL FIELD

Embodiments of the present disclosure are in the field of renewable energy and, in particular, apparatuses for, and methods of, fabricating solar cell emitter regions using ion implantation.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

### BRIEF DESCRIPTION OF THE DRAWINGS

FIG. 1 illustrates a cross-sectional view of a solar cell emitter region fabrication apparatus.

FIG. 2 illustrates a cross-sectional view of a semiconductor wafer having emitter region fingers.

FIG. 3 is a graphical representation of nonuniform finger widths of emitter region fingers on a semiconductor wafer.

FIG. 3A illustrates experimental results corresponding to FIG. 3.

FIG. 4 is a graphical representation of nonuniform finger pitches of emitter region fingers on a semiconductor wafer.

FIG. 4A illustrates experimental results corresponding to FIG. 4.

FIG. 5 illustrates nonuniform finger widths of emitter region fingers resulting from ion beam divergence.

FIG. 6 illustrates uniform finger widths of emitter region fingers resulting from compensated mask opening widths of a species mask.

FIG. 7 illustrates nonuniform finger pitches of emitter region fingers resulting from temperature-induced strain in a semiconductor wafer.

FIG. 8 illustrates uniform finger widths and pitches of emitter region fingers resulting from compensated mask opening widths and pitches of a species mask.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, or the following detailed description.

This specification includes references to “one embodiment” or “an embodiment.” The appearances of the phrases “in one embodiment” or “in an embodiment” do not necessarily refer to the same embodiment. Particular features, structures, or characteristics can be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. § 112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” pair of mask openings does not necessarily imply that this pair is the first pair in a sequence; instead the term “first” is used to differentiate this pair from another pair (e.g., a “second” pair of mask openings).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Placement of the doped regions within the substrate is an important characteristic of a solar cell as it is directly related to the capability of the solar cell to generate power. More particularly, accuracy and uniformity of patterns of the doped regions is directly related to an efficacy of the solar cell. Accordingly, apparatuses and methods for accurately and uniformly forming doped regions within the substrate during the manufacture of solar cells is generally desirable.

Apparatuses for, and methods of, fabricating solar cell emitter regions using ion implantation, and the resulting solar cells, are described herein. In the following description, numerous specific details are set forth, such as specific process operations, in order to provide a thorough understanding of embodiments of the present disclosure. It will be apparent to one skilled in the art that embodiments of the present disclosure can be practiced without these specific details. In other instances, well-known fabrication techniques are not described in detail in order to not unnecessarily obscure embodiments of the present disclosure. Furthermore, it is to be understood that the various embodiments shown in the figures are illustrative representations and are not necessarily drawn to scale.

Disclosed herein are apparatuses for, and methods of, fabricating solar cells, and more particularly, solar cell emitter regions. In one embodiment, a solar cell emitter region fabrication apparatus includes a plasma source and a semiconductor wafer having a top surface. The apparatus includes a species mask located between the plasma source and the semiconductor wafer. Furthermore, the species mask can include several mask openings sized and located to compensate for causes of non-uniformity in solar cell emitter regions. More particularly, the species mask can include mask openings having respective opening widths and respective opening pitches. The opening widths and/or pitches can be nonuniform such that species from the plasma source pass through the mask openings to directly implant into the top surface of the semiconductor wafer. The implemented species can form several emitter region fingers in the semiconductor wafer, and the fingers can have uniform finger widths and uniform finger pitches.

To provide context, current methods of printing emitter region fingers in solar cell wafers through mask and ion implantation result in emitter region fingers having nonuniform width and/or pitch. Uniformity of finger width and pitch, however, is critical to cell performance. As described below, multiple factors can cause the non-uniformities. By way of example, the factors include temperature gradients in the solar cell wafers and divergence of an ion beam used to implant ions in the solar cell wafers. To date, there is no well-established solution for controlling such factors. Furthermore, proposed solutions for controlling such factors directly would likely be costly and time-consuming to implement. The solar cell emitter region fabrication apparatus described below, however, provides an inexpensive and quickly implementable solution to compensate for ion beam non-uniformity, rather than controlling the contributing factors directly.

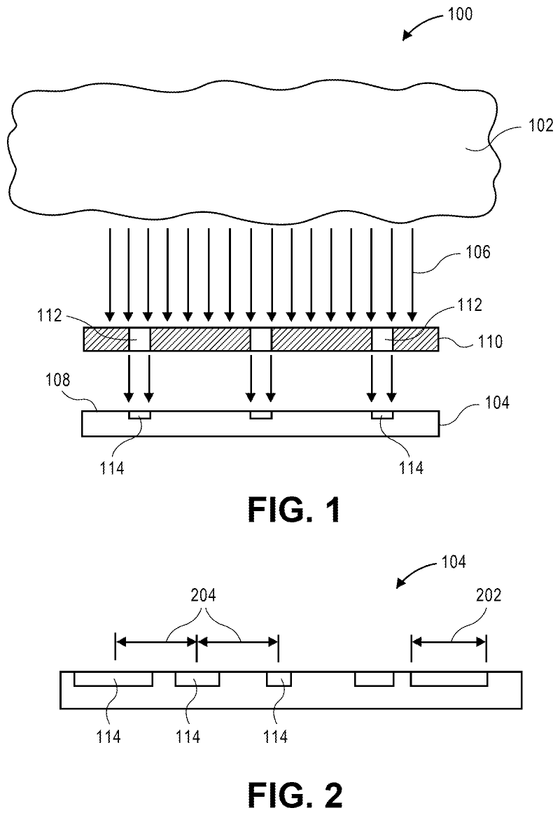

Referring to FIG. 1, a cross-sectional view of a solar cell emitter region fabrication apparatus is shown. In an embodiment, plasma source 102 generates an ion beam 106. For example, ion beam 106 can include species, e.g., a dopant species, directed toward semiconductor wafer 104. The dopant species can include P+ dopant atoms for silicon, e.g., boron atoms. Alternatively, the dopant species can include N+ dopant atoms for silicon, e.g., nitrogen, phosphorus, or arsenic atoms.

Semiconductor wafer 104 can include a silicon layer and/or a thin oxide layer disposed on a substrate. For example, the substrate can be a mono crystalline silicon substrate or a polycrystalline silicon substrate. The substrate can be a single crystalline N-type doped silicon substrate. It is to be understood, however, that semiconductor wafer 104 can include a layer, such as a multi-crystalline or amorphous silicon layer, disposed on a global solar cell substrate. In any case, semiconductor wafer 104 can include a top surface 108 facing plasma source 102.

In an embodiment, solar cell emitter region fabrication apparatus 100 includes a species mask 110 disposed between plasma source 102 and semiconductor wafer 104. For example, species mask 110 can be a shadow mask, e.g., a graphite shadow mask. Species mask 110 can include several mask openings 112 extending from a first side of species mask 110 facing plasma source 102 to a second side of species mask 110 facing semiconductor wafer 104. The mask openings 112 can form a slit pattern. Accordingly, species can travel directly from plasma source 102 through mask openings 112 to top surface 108 of semiconductor wafer 104. More particularly, mask openings 112 can pass or transmit the species from plasma source 102 to semiconductor wafer 104 such that the species implant into top surface 108. That is, a dopant impurity species of a conductivity type can be implanted in semiconductor wafer 104. Accordingly, emitter region fingers 114 can be printed directly on semiconductor wafer 104. Such direct printing can be contrasted with, e.g., patterning using optical lithography through photoresists. The implanted dopant impurity species form several emitter region fingers 114 on semiconductor wafer 104.

Ion beam 106 can include P+ dopant atoms, and thus, emitter region fingers 114 can be referred to as p-fingers. In contrast, ion beam 106 can include N+ dopant atoms, and thus, emitter region fingers 114 can be referred to as n-fingers. In an embodiment, boron is implanted to form the p-fingers, which imparts etch resistance to the p-fingers, and nitrogen is implanted to form the n-fingers. In an operation (not shown), the non-implanted regions of semiconductor wafer 104, e.g., the areas of top surface 108 laterally between emitter region fingers 114, can be etched by a selective etch process to preserve the modified p-doped and n-doped regions. Accordingly, interdigitated p-fingers and n-fingers can be formed in top surface 108 of semiconductor wafer 104. The interdigitated p-fingers and n-fingers can be formed by successive implantation processes utilizing a same or different mask 110.

Referring to FIG. 2, a cross-sectional view of a semiconductor wafer having emitter region fingers is shown. A placement and size of p-fingers and n-fingers should be precise for optimal cell performance. More particularly, each emitter region finger 114 can include a finger width 202, and each pair of adjacent emitter region fingers 114 can be spaced apart by a finger pitch 204. Solar cell performance can improve when the emitter region fingers 114 have respective uniform finger widths 202, i.e., when all or most finger widths 202 of the emitter region fingers 114 are equal. Similarly, solar cell performance can improve when the emitter region fingers 114 have respective uniform finger pitches 204, i.e., when all or most pairs of emitter region fingers 114 are spaced apart by a same finger pitch 204.

Still referring to FIG. 2, although uniform finger widths and finger pitches can provide ideal cell performance, in real practice there are difficult-to-control factors that result in nonuniform finger widths or pitches. More particularly, emitter region fingers 114 fabricated by existing mask and ion implantation techniques may produce nonuniform finger widths and finger pitches. For example, respective finger widths 202 of the emitter region fingers 114 may vary across semiconductor wafer 104. Similarly, respective finger pitches 204 between different pairs of adjacent emitter region fingers 114 may vary across semiconductor wafer 104. As described below, it has been shown that variations in finger pitch 204 and finger width 202 may differ depending on whether the emitter region fingers 114 are n-fingers or p-fingers.

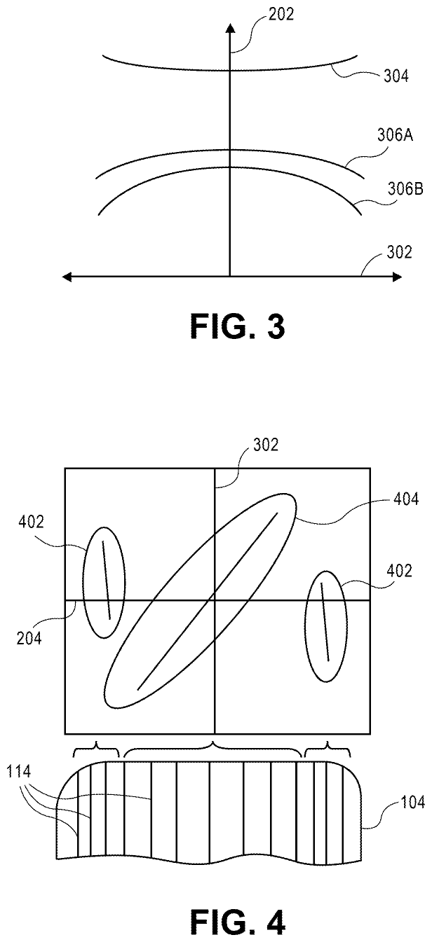

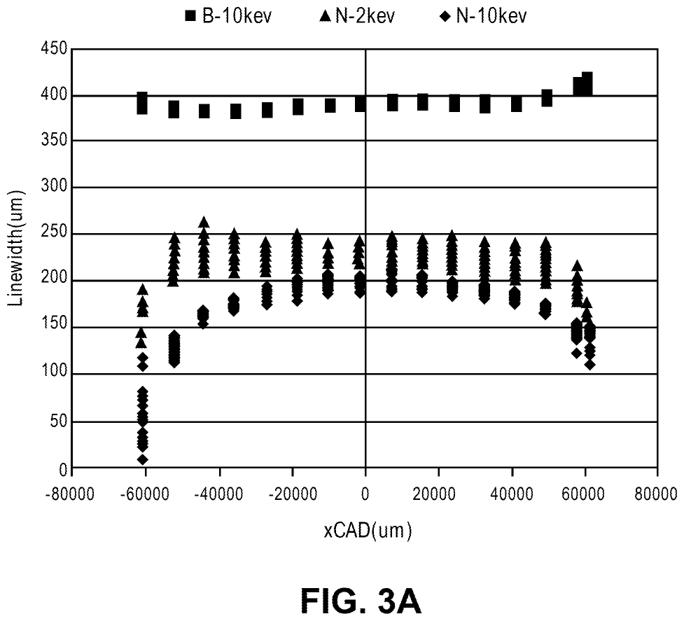

Referring to FIG. 3, a graphical representation of nonuniform finger widths of emitter region fingers on a semiconductor wafer is shown. The graph represents finger width 202 of emitter region fingers 114 along the Y-axis plotted against a radial distance 302 from a center or a centerline of semiconductor wafer 104, as represented by the X-axis. A p-finger graph line 304 includes a U-shape indicating that finger width 202 of p-fingers increases in a radial direction from the centerline of semiconductor wafer 104. That is, finger width 202 of p-fingers can have a positive relationship to a radial distance 302 from the centerline, where the finger width 202 increases with an increase in the radial distance 302. Several n-finger graph lines 306a and 306b include an inverted U-shape indicating that the finger width 202 of n-fingers decreases in a radial direction from the centerline of semiconductor wafer 104. That is, finger width 202 of n-fingers can have a negative relationship to a radial distance 302 from the centerline, where the finger width 202 decreases with an increase in the radial distance 302. Experimental results corresponding to FIG. 3 are illustrated in FIG. 3A.

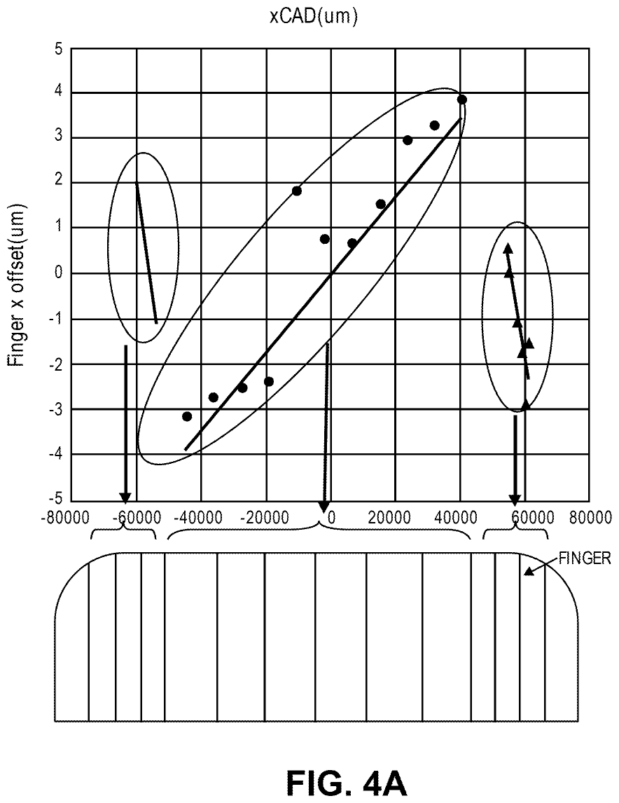

Referring to FIG. 4, a graphical representation of nonuniform finger pitches of emitter region fingers on a semiconductor wafer is shown. The graph represents finger pitch 204 of pairs of emitter region fingers 114 along the X-axis plotted against a radial distance 302 from a center or a centerline of semiconductor wafer 104 as represented by the Y-axis. The finger offset distribution shows that lateral regions 402 of semiconductor wafer 104 include smaller finger pitches 204 than a central region 404 of semiconductor wafer 104. More particularly, pairs of emitter region fingers 114 located nearer to the centerline of semiconductor wafer 104 tend to have larger finger pitches 204 than pairs of emitter region fingers 114 located farther from the centerline in a radial direction. Experimental results corresponding to FIG. 4 are illustrated in FIG. 4A.

Non-uniformity of finger pitch 204 and finger width 202 of emitter region fingers 114 as described above with respect to FIGS. 3-4 can result from several causes. Solar cell emitter region fabrication apparatus 100 can compensate for these causes as described below to form emitter region fingers 114 having uniform finger widths 202 and finger pitches 204 across semiconductor wafer 104.

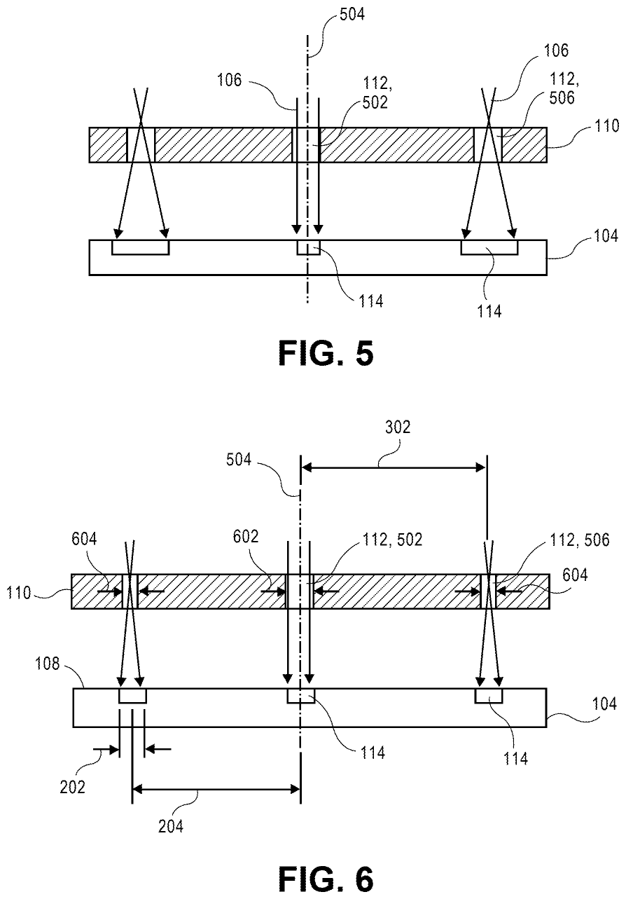

Referring to FIG. 5, nonuniform finger widths of emitter region fingers resulting from ion beam divergence is shown in accordance with an embodiment of the present disclosure. Non-uniformity of finger width 202 can result from nonuniform ion beam divergence angles. Species mask 110 can intercept ion beam 106 as the species travel toward semiconductor wafer 104. Accordingly, a finger width 202 of an emitter region finger 114 underlying a given mask opening 112 can depend on an angle of the ion beam 106 passing through the opening relative to a longitudinal axis of the opening. For example, ion beam 106 passing through a middle opening 502 of FIG. 5 can be parallel to a centerline 504 of semiconductor wafer 104 extending through middle opening 502, and thus, the underlying emitter region finger 114 can have a same width as middle opening 502. By contrast, ion beam 106 passing through a lateral opening 506 of FIG. 5 can be oblique to a respective line extending through lateral opening 506, and thus, can have a larger width than lateral opening 506. Accordingly, uniform opening widths in species mask 110 can translate to nonuniform finger widths 202 on semiconductor wafer 104 due to beam divergence.

Referring to FIG. 6, uniform finger widths of emitter region fingers resulting from compensated mask opening widths of a species mask is shown in accordance with an embodiment of the present disclosure. Compensation can be provided for ion beam divergence. In an embodiment, semiconductor wafer 104 includes centerline 504 extending orthogonal to the top surface 108 and species mask 110. Mask openings 112 of species mask 110 can have respective nonuniform opening widths to compensate for the ion beam divergence. Respective nonuniform opening widths of mask openings 112 can have a negative relationship to a radial distance 302 from centerline 504. For example, middle opening 502 can have a wide opening width 602 and lateral opening 506 can have a narrow opening width 604. The terms wide and narrow are used here as relative terms, i.e., wide opening width 602 includes a larger dimension, such as a larger cross-sectional dimension, than narrow opening width 604. Nonetheless, the cross-sectional dimensions of all mask openings 112 can be on the order of several hundred microns. Accordingly, mask opening size can decrease with greater radius from centerline 504, and mask opening pitch can increase with greater radius from centerline 504.

Narrow opening width 604 can result in a smaller angle of divergence of ion beam 106 as the species pass through lateral opening 506, and thus, emitter region finger 114 under lateral opening 506 can have a same finger width 202 as emitter region finger 114 under middle opening 502, despite narrow opening width 604 being smaller than wide opening width 602. In an embodiment, finger pitch 204 between emitter region fingers 114 can match distances between mask openings 112, e.g., finger pitches 204 can be uniform. In some scenarios, however, finger pitches 204 can vary even though finger widths 202 are corrected to be uniform. Accordingly, solutions for correcting pitch non-uniformity may be needed as described below.

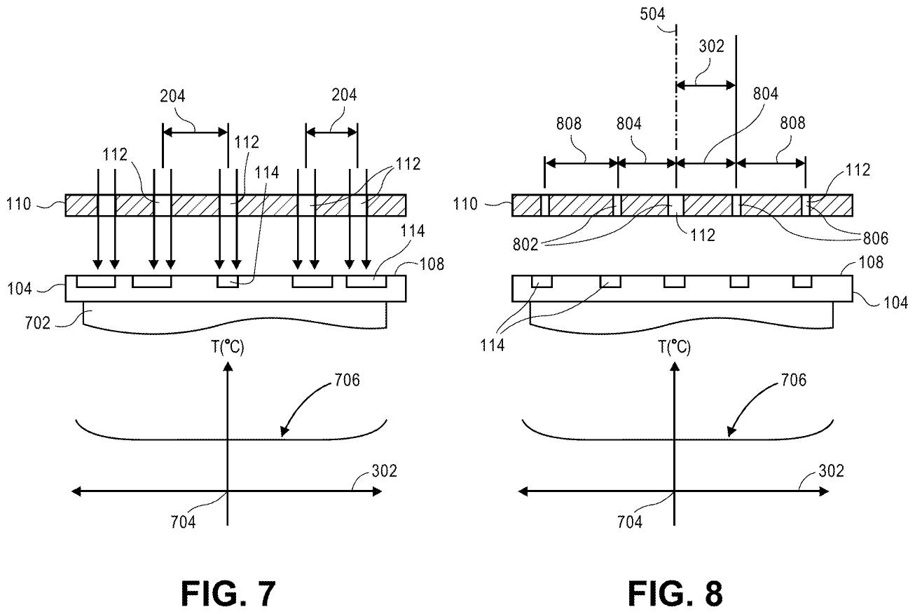

Referring to FIG. 7, nonuniform finger pitches of emitter region fingers resulting from temperature-induced strain in a semiconductor wafer is shown in accordance with an embodiment of the present disclosure. Non-uniformity of finger width 202 and/or pitch 204 can result from temperature-induced strain based on radial distance 302 from centerline 504. In an embodiment, solar cell emitter region fabrication apparatus 100 includes an electrostatic chuck 702 to hold semiconductor wafer 104. That is, semiconductor wafer 104 can be mounted on electrostatic chuck 702 such that a center of semiconductor wafer 104 is aligned with a center 704 of electrostatic chuck 702 along the centerline 504.

Electrostatic chuck 702 can induce a temperature gradient 706 within semiconductor wafer 104. For example, temperature gradient 706 of semiconductor wafer 104 can increase radially outward from center 704 such that a temperature of semiconductor wafer 104 is greater nearer to an outward edge of the wafer than a temperature of semiconductor wafer 104 nearer to centerline 504. Dynamic heating of semiconductor wafer 104 by electrostatic chuck 702, mask 110, and/or the ion beam can cause thermal expansion of the wafer such that top surface 108 expands outward while the ion beam impinges upon the surface. Accordingly, emitter region fingers 114 nearer to center 704 can be narrower than emitter region fingers 114 nearer to the rim of semiconductor wafer 104 because the surface can float under the impinging beam. Furthermore, a finger pitch 204 between pairs of laterally disposed emitter region fingers 114 can be less than finger pitch 204 between pairs of emitter region fingers 114 near center 704.

Referring to FIG. 8, uniform finger widths and pitches of emitter region fingers resulting from compensated mask opening widths and pitches of a species mask is shown in accordance with an embodiment of the present disclosure. Solar cell emitter region fabrication apparatus 100 can compensate for temperature-induced strain in semiconductor wafer 104. In an embodiment, mask openings 112 of species mask 110 can have respective nonuniform opening pitches to compensate for the thermal expansion and/or contraction. Respective nonuniform opening pitches between pairs of mask openings 112 can have a positive relationship to a radial distance 302 from centerline 504. For example, a first pair of mask openings 802 nearer to centerline 504 can have a narrow opening pitch 804, and a second pair of mask openings 806 farther from centerline 504 can have a wide opening pitch 808. The terms wide and narrow are used here as relative terms, i.e., wide opening pitch 808 can include a greater distance than narrow opening pitch 804.

In an embodiment, the opening widths of mask openings 112 can also vary across species mask 110. For example, mask openings 112 nearer to the rim of species mask 110 can have smaller opening widths than mask openings 112 nearer to centerline 504 of species mask 110.

Based on the nonuniform opening widths and/or opening pitches in species mask 110, ion beam 106 can pass through species mask 110 and impinge on semiconductor wafer 104 such that several emitter region fingers 114 having uniform finger widths 202 and uniform finger pitches 204 are formed on top surface 108. Accordingly, nonuniform width and pitch of emitter region fingers 114 can be corrected by compensating for one or both of opening widths or opening pitches in species mask 110.

In an embodiment, solar cell emitter region fabrication apparatus 100 can include a second species mask (not shown) between plasma source 102 and semiconductor wafer 104. The second species mask can be provided between plasma source 102 and species mask 110 or between species mask 110 and semiconductor wafer 104. Openings in the second species mask can be manipulated to alter one or more dimensions of or a uniformity of the ion beam flux. For example, reducing a width of openings in the second species mask can reduce a dimension of the ion beam flux to make the ion beam spots impinging on semiconductor wafer 104 the same. That is, the ion beam spots can have similar dimensions to form emitter region fingers 114 of uniform widths across semiconductor wafer 104. Thus, the ion beam 106 can be manipulated to compensate for variations in process parameters and form emitter region fingers 114 having uniform widths and pitches across top surface 108 of semiconductor wafer 104. In an example, one mask can have uncompensated openings and can be utilized with one or more secondary masks that provide compensation of an ion beam flux to provide emitter region fingers that have uniform widths and pitches. In another example, the species mask 110 is uncompensated and one or more dimensions of or a uniformity of the ion beam flux is compensated so that emitter region fingers are formed on a semiconductor that have uniform widths and pitches. The ion beam flux can be compensated via, for example, a second species mask as discussed above, a collimator, or another structure that provides a mask function similar to that of the second species mask discussed above.

It is to be appreciated that fabrication of a species mask can be performed by forming, e.g., cutting or etching, slits in a uniform sample of material. However, in another aspect, a species mask is fabricated using a stack of material layers that can be cut or etched to provide a slit pattern therein. In one such embodiment, individual layers of silicon wafers are stacked and bonded to one another, and slits are formed therein.

Overall, although certain materials are described specifically above, some materials can be readily substituted with others. For example, in an embodiment, a different material substrate, such as a group III-V material substrate, can be used to form semiconductor wafer 104 instead of a silicon substrate. In another embodiment, a polycrystalline or multi-crystalline silicon substrate is used. Furthermore, an ordering of N+ and P+ type doping can occur in different sequences in different embodiments.

In general, embodiments described herein can be implemented to precisely form emitter region fingers 114 on semiconductor wafer 104. Thus, apparatuses for, and methods of, fabricating solar cell emitter regions using ion implantation, and the resulting solar cells, have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of this disclosure.

The scope of the present disclosure includes any feature or combination of features disclosed herein (either explicitly or implicitly), or any generalization thereof, whether or not it mitigates any or all of the problems addressed herein. Accordingly, new claims can be formulated during prosecution of this application (or an application claiming priority thereto) to any such combination of features. In particular, with reference to the appended claims, features from dependent claims can be combined with those of the independent claims and features from respective independent claims can be combined in any appropriate manner and not merely in the specific combinations enumerated in the appended claims.

What is claimed is:

1. A species mask to be provided between a plasma source and a semiconductor wafer comprising:
a plurality of mask openings to pass species from the plasma source to the semiconductor wafer such that the species implant into a top surface to form a plurality of emitter region fingers on the semiconductor wafer, wherein the plurality of mask openings have one or more of respective nonuniform opening widths or respective nonuniform opening pitches such that the plurality of emitter region fingers have respective uniform finger widths and respective uniform finger pitches.

2. The species mask according to claim 1, wherein the species travel from the plasma source through the plurality of mask openings into the top surface of the semiconductor wafer.

3. The species mask according to claim 1, wherein the semiconductor wafer includes a centerline extending orthogonal to the top surface and the species mask, and wherein a respective nonuniform opening width of a respective mask opening has a negative relationship to a radial distance of the respective mask opening from the centerline.

4. The species mask according to claim 1, wherein the semiconductor wafer includes a centerline extending orthogonal to the top surface and the species mask, and wherein a respective nonuniform opening pitch between a pair of mask openings has a positive relationship to a radial distance of the pair of mask openings from the centerline.

5. The species mask according to claim 1, wherein the species mask is a shadow mask.

6. The species mask according to claim 1, wherein the semiconductor wafer is mounted on an electrostatic chuck, and wherein a temperature gradient of the semiconductor wafer increases radially outward from a center of the semiconductor wafer.

7. The species mask according to claim 1, wherein the species mask has slot openings of variable widths to compensate edge effects of an ion beam, non-uniform wafer temperatures, and/or chuck edge effects to result in uniform implanted patterns on the semiconductor wafer.

8. The species mask according to claim 1, wherein the plurality of mask openings have respective opening pitches that are varied so that the plurality of emitter region fingers have uniform finger pitches.

9. A method of fabricating a solar cell, comprising:
providing a species mask between a plasma source and a semiconductor wafer, the species mask comprising a plurality of mask openings to pass species from the plasma source to the semiconductor wafer such that the species implant into a top surface to form a plurality of emitter region fingers on the semiconductor wafer, wherein the plurality of mask openings have one or more of respective nonuniform opening widths or respective nonuniform opening pitches such that the plurality of emitter region fingers have respective uniform finger widths and respective uniform finger pitches; and
delivering the species from the plasma source through the plurality of mask openings into the top surface of the semiconductor wafer.

10. The method according to claim 9, wherein the semiconductor wafer includes a centerline extending orthogonal to the top surface and the species mask, and wherein a respective nonuniform opening width of a respective mask opening has a negative relationship to a radial distance of the respective mask opening from the centerline.

11. The method according to claim 9, wherein the semiconductor wafer includes a centerline extending orthogonal to the top surface and the species mask, and wherein a respective nonuniform opening pitch between a pair of mask openings has a positive relationship to a radial distance of the pair of mask openings from the centerline.

12. The method according to claim 9, wherein the species mask is a shadow mask.

13. The method according to claim 9, wherein the semiconductor wafer is mounted on an electrostatic chuck, and wherein a temperature gradient of the semiconductor wafer increases radially outward from a center of the semiconductor wafer.

14. The method according to claim 9, wherein the species mask has slot openings of variable widths to compensate edge effects of an ion beam, non-uniform wafer temperatures, and/or chuck edge effects to result in uniform implanted patterns on the semiconductor wafer.

15. The method according to claim 9, wherein the plurality of mask openings have respective opening pitches that are varied so that the plurality of emitter region fingers have uniform finger pitches.

16. A semiconductor fabrication apparatus, comprising:
a shadow mask; and
a plurality of mask openings in the shadow mask, wherein the plurality of mask openings have one or more of respective nonuniform opening widths or respective nonuniform opening pitches.

17. The semiconductor fabrication apparatus according to claim 16, wherein a respective nonuniform opening width of a respective mask opening has a negative relationship to a radial distance of the respective mask opening from a centerline of a semiconductor wafer.

18. The semiconductor fabrication apparatus according to claim 16, wherein a respective nonuniform opening pitch between a pair of mask openings has a positive relationship to a radial distance of the pair of mask openings from a centerline of a semiconductor wafer.

19. The semiconductor fabrication apparatus according to claim 16, wherein the shadow mask has slot openings of variable widths to compensate edge effects of an ion beam, non-uniform wafer temperatures, and/or chuck edge effects to result in uniform implanted patterns on a semiconductor wafer.

20. The semiconductor fabrication apparatus according to claim 16, wherein the shadow mask is a graphite shadow mask.
